(19) United States
(12) Patent Application Publication
(10) Pub. No.: US 2007/0085477 A1
(43) Pub. Date: Apr. 19, 2007

(54) Barrier thin film, and organic el element using the barrier thin film

(76) Inventor: Hirofumi Kubota, Saitama (JP)

Correspondence Address: SUGHRUE MION, PLLC, 2100 PENNSYLVANIA AVENUE, N.W., SUITE 800, WASHINGTON, DC, 20037, US

(21) Appl. No.: 10/579,060

(22) PCT Filed: Nov. 9, 2004
(86) PCT No.: PCT/JP04/16561

§ 371 Date: Aug. 29, 2006

(30) Foreign Application Priority Data
Nov. 11, 2003 (JP) 2003-381403

(51) Int. Cl. H05B 33/06; H05B 33/00; H01L 51/50

(52) U.S. Cl. 313/512; 313/509; 313/504

(57) ABSTRACT

A barrier thin film having a sufficient flexibility while providing the excellent barrier property without suffering from a pin hole or the like, and furthermore, without the risk of damaging the substance to be covered with the barrier is provided. The barrier thin film is provided as a single thin film while a property thereof is changed continuously from one side surface to the other side surface instead of having a homogeneous property.

### TECHNICAL FIELD

The present invention relates to a barrier thin film used for preventing permeation of water or oxygen from outside, and an organic EL element using the same.

### BACKGROUND ART

As an electroluminescent element (EL element), which is also referred to as an electroluminescence element, nowadays an inorganic EL element using an inorganic material as a fluorescent material, and an organic EL element using an organic material are utilized. Particularly, the organic EL element is configured by interposing a thin film made mainly of a fluorescent organic compound between an anode and a cathode. An exciton is produced by injecting electrons and positive holes into the thin film so as to re-bond them and emit a light beam utilizing light (fluorescence, phosphorescence) emission at the time the exciton is deactivated. Since the organic EL element has the excellent characteristics as a display such as high contrast, high speed response, high illuminance and high view angle, it may be utilized in various fields.

However, such an organic EL element can easily be damaged by water as well as an organic solvent, so that as the use time of the organic EL element becomes longer, the risk of invasion of water and oxygen into the organic EL element becomes higher, which leads to deterioration of the organic EL element. In particular, one of grave problems of the organic EL element is a generation of the dark spot (non light emitting region). A circular dark spot is generated and enlarged by oxidation or separation of the cathode at the cathode-organic film interface due to the influence of the water entering from defects of a cathode such as a pin hole, which give rise to the significant deterioration of display quality or illuminance reduction.

Then, conventionally, for prolonging the life of the organic EL element, a barrier thin film has been used for preventing permeation of the water and the oxygen from the outside (for example, see patent document 1).

Patent document 1: Japanese Patent Application Laid-Open No. 2003-109753 (JP2003-109753A)

### DISCLOSURE OF THE INVENTION

### Problems to be Solved by the Invention

However, since most of the conventional barrier thin films have been formed with a simple inorganic substance (or inorganic oxide), the thickness of the film should be set an increased level in order to prevent the film from the generation of the dark spot as mentioned above. However, the larger the film thickness of the barrier thin film is, the larger the film stress of the barrier thin film becomes, so that the organic EL element itself may be damaged or separated when the conventional barrier thin film is used for an organic EL element. Moreover, although the organic EL element can be made thinner and thus it can enjoy an excellent flexibility so as to provide an organic EL element having the excellent flexibility as a whole according to the kind of the substrate to be used (for example a film substrate), such an advantage would be spoiled by using the thicker barrier thin film as mentioned above.

The present invention has been made under such circumstances, and an object thereof is to provide a barrier thin film which is used for preventing permeation of the water and the oxygen from the outside into an article, for example, an organic EL element, and which has an excellent barrier property without suffering from a pin hole or the like, and has a low stress, and which is free from the risk of damaging the article to be covered with the barrier.

### MEANS FOR SOLVING THE PROBLEMS

A barrier thin film according to claim 1, for solving the above-mentioned problems, is a barrier thin film for preventing permeation of water and oxygen from the outside, the film having a property changing continuously from its one side surface to the other side surface.

An organic EL element according to claim 5, for solving the above-mentioned problems, is an organic EL element using the barrier thin film according to any of claims 1 to 3.

### BRIEF DESCRIPTION OF THE DRAWINGS

FIG. 1 is an entire configuration diagram showing an organic EL element using a barrier thin film of the present invention.

### DESCRIPTION OF THE REFERENCE NUMERALS

10 organic EL element
11 transparent substrate
12 anode electrode
13 organic light emitting layer
14 cathode electrode
15 barrier thin film

### BEST MODE FOR CARRYING OUT THE INVENTION

Hereinafter, the barrier thin film of the present invention will be explained. For explaining the barrier thin film of the present invention more specifically, hereinafter, an example of the case of using the barrier thin film of the present invention for an organic EL element will be explained.

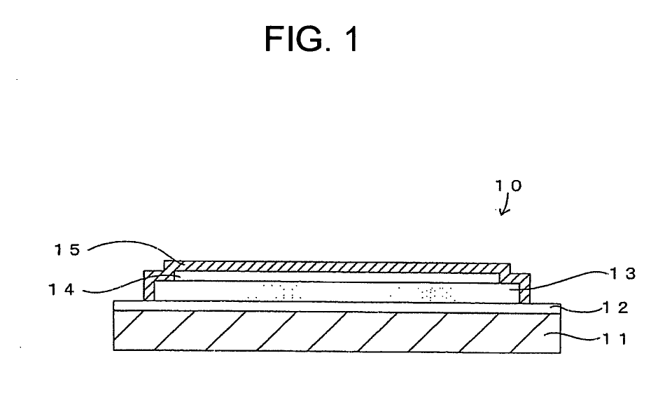

FIG. 1 is an entire configuration diagram showing an organic EL element 10 using a barrier thin film of the present invention.

As shown in FIG. 1, the organic EL element 10 comprises a transparent substrate 11, an anode electrode 12 formed on the transparent substrate 11, an organic light emitting layer 13 formed on the anode electrode 12, and a cathode electrode 14 formed on the organic light emitting layer 13. Moreover, a barrier thin film 15 of the present invention is formed on the uppermost layer side of the laminated structure so as to cover the entire element.

Here, the transparent substrate 11 in the present invention is not particularly limited, and it can be for example a film substrate or a glass substrate. It can be selected optionally according to the situation that the organic EL element is used or the required performance thereof.

The barrier thin film 15 of the present invention is characterized in that it is formed so that a property is changed from its one side surface to the other side surface.

Accordingly, although the barrier thin film of the present invention is a single thin film, the property continuously changes from its one side surface to the other side surface (that is, in the thickness direction) instead of having a homogeneous property, so that different two roles can be played by the front side and the rear side of the thin film. Further, since the barrier thin film of the present invention is still a single thin film, the production thereof is easy as compared with that of a thin film formed by laminating a plurality of layers of different properties, and furthermore, the cost can be reduced.

As mentioned above, since the barrier thin film of the present invention is characterized in that it performs the different effects on the front side and the rear side thereof while it is a single thin film, and thus the concrete properties of each of the front side and the rear side may be set arbitrarily according to the situation that the barrier thin film is used or the required performance thereof.

For example, in the case of using the barrier thin film of the present invention for the organic EL element 10 shown in FIG. 1, it is preferable to employ the film having as the property a hardness changing from a low hardness to a high hardness, more specifically, a hardness changing continuously from a low hardness at the surface on the side contacting with the organic light emitting layer 13 or the cathode electrode 14 (hereinafter, this side may be referred to merely as the “rear side”) to a high hardness at the surface on the side contacting with the outside (hereinafter, this side may be referred to merely as the “front side”). Although the organic light emitting layer 13 is thin and soft and can be damaged considerably easily, to sustain damage on the organic light emitting layer 13 can be prevented by forming the surface of the barrier thin film 15 to be directly contacted with the organic light emitting layer 13 or the like, that is, the rear side of the barrier thin film to have the property of the low hardness. Moreover, the low hardness denotes the softness, and the soft portion plays the roll of alleviating the stress even in the case it is changed to the high hardness having a high barrier property toward the front side, which results in preventing separation of the barrier thin film 15.

Here, the most important purpose of the barrier thin film of the present invention to be used for the organic EL element 10 is to prevent penetration of water and oxygen from the outside to the organic light emitting layer 13 or the like. According to the continuous change to the high hardness from the rear side of the above-mentioned barrier thin film 15 to the surface to be contacted with the out side (hereinafter, this side may be referred to simply as the “front side”), penetration of the water or oxygen from the outside to the organic light emitting layer 13 or the like can be prevented, and as a result deterioration of the organic EL element can be prevented.

Lamination of a thin film A having a relatively soft nature with flexibility and a thin film B having a relatively hard and strong nature with a rich barrier property can be conceived, in order to obtain the same function as the barrier layer of the present invention, that is, in order to provide a relatively soft nature with flexibility on the rear side of the barrier thin film and on the other hand a relatively hard and strong nature with a rich barrier property on the front side of the barrier thin film. However, in the case a plurality of thin films having different properties are laminated, a boundary portion is vulnerable to the force applied from the outside, and furthermore, exfoliation may be occurred from the boundary portion. On the other hand, since the barrier thin film of the present invention does not have a boundary in the film (that is, it is a single layer as a whole) and only the property is changed continuously, the problem of the exfoliation cannot be occurred. Moreover, since the film forming material needs not be changed drastically, the cost can be reduced as well.

Here, the method for continuously changing the hardness of the barrier thin film from the low hardness to the high hardness as mentioned above is not particularly limited in the present invention, and any method can be adopted. Concretely, the hardness of the barrier thin film can be changed by providing the barrier thin film of the present invention with an inorganic substance (or an inorganic oxide) as the main component, containing carbon and/or hydrogen therein, and adjusting the content ratio. For example, in the case of using a silicon oxide as the inorganic substance to be the main component of the barrier thin film, if the content ratio of the carbon and/or hydrogen is low, the barrier thin film has the inorganic nature so that a hard and strong thin film can be obtained. On the other hand, if the carbon and/or hydrogen is contained by a large amount (the content ratio of the carbon and/or hydrogen is of a high content ratio), the barrier thin film has the organic nature so that a flexible thin film having the rich flexibility can be obtained.

Hereinafter, embodiments of the barrier thin film of the present invention will be explained together with a specific manufacturing method.

### FIRST EMBODIMENT

A barrier thin film of the present invention can be manufactured by the plasma CVD method using a diamond-like carbon (hereinafter, it is referred to as the “DLC”) as raw material (that is, the main component of the barrier thin film is DLC)

In this case, at the time of forming a film of the DLC by the plasma CVD method, the rear side of the barrier thin film can be formed as a polymer-like soft film and the outer side as a diamond-like hard film with a high barrier property by increasing the RF power applied to the substrate continuously. Further specifically, since a thin film using a DLC becomes a harder diamond-like film with a high barrier property with a larger internal stress, the RF power is increased continuously so as to control the internal stress distribution of the DLC film to be larger from the rear side toward the front side. That is, since the internal stress of the DLC film becomes larger as the applied RF power increased, the internal stress is made smaller on the rear side of the barrier thin film and can be made larger toward the front side by increasing the applied RF power during the film formation. Moreover, in order to further improve the gas barrier characteristics in the DLC film, the RF power may be applied constantly in the final stage of the DLC film formation.

According to the manufacturing method, the internal stress distribution of the barrier thin film formed from DLC can be changed continuously. Thus, the adhesion force of the DLC film can be improved as well as the stress of the film having the high hardness and the high barrier property can be alleviated by the soft film on the rear side, exfoliation of the film can be prevented as well as the high gas barrier characteristics can be ensured. Therefore, the introduction of the water or oxygen from the outside can certainly be prevented so as to prolong the life of the element. Moreover, since the DLC film contains hydrogen atoms so as to have the spatial margin in the atomic sequence, elastic deformation can be enabled.

### SECOND EMBODIMENT

A barrier thin film of the present invention can be manufactured by the plasma CVD method as mentioned above using HMDS (1,1,1,3,3,3-hexamethyldisilazene) and N (nitrogen) or NH₃ (ammonium) as raw materials. The main component of the barrier thin film produced by this method is a SiN (silicon nitride).

According to this method, since the N (nitrogen) in the film is increased and the C (carbon) and H₂ (hydrogen) are decreased by raising the RF power during the film formation, a continuous inorganic film (with a high barrier property) can be also obtained.

More specifically, by forming a film using the cathode coupling type PE-CVD, the C produced by the decomposition of the HMDS are contained in the film in addition to the Si and the N as constituent elements. Here, since the C/Si ratio in the film is decreased and the N/Si ratio is increased as the RF power during the film formation is increased, a film having a property changing continuously from the low hardness to the high hardness can be produced.

According to the production method of the second embodiment, that is, in the case of producing a barrier thin film of the present invention by the plasma CVD method using the HMDS (hexamethyldisilazene) as the material, the property of the barrier thin film of the present invention can also be changed continuously by a method other than the above-mentioned RF power adjustment, for example, by changing the substrate temperature.

More specifically, since the film density is low in a film formed at a low temperature, a soft film having a rich flexibility can be formed. Therefore, by manufacturing the barrier thin film while gradually raising the temperature, a barrier film which is soft on the rear side and becomes harder toward the front side can be obtained.

Moreover, the property of the film can be changed as well by changing the flow rate ratio of the HMDS to be used as the raw material.

Furthermore, although the HMDS is used as the raw material in the second embodiment, TMOS (tetramethoxy silane) and O₂ (oxygen) can be used as alternative raw materials. In this case, the main component of the barrier thin film of the present invention is SiO₂ (silicon oxide).

In this case, as a method for continuously changing the component of the barrier thin film, a technique of changing the partial pressure ratio of the TMOS/O₂ so as to reduce the content of the carbon and/or the hydrogen as the impurities and thus to harden the thin film can be exemplified.

Examples of the production method for the barrier thin film have been mentioned above, and according to the production method, the production process can be simplified. That is, since the barrier thin film of the present invention has the shape of a single layer while having multiple properties, it can be produced with one chamber as the manufacturing unit only by changing the condition continuously by the method as mentioned above (in general, for producing thin films having different properties, a plurality of the chambers are needed which complicates the production process and thereby drastically increase the cost).

As heretofore explained, according to the barrier thin film of the present invention, the organic light emitting layer or the like cannot be damaged, and the flexibility of the organic EL element cannot be spoiled in the case for example it is used as the barrier thin film for an organic EL element, since the rear side thereof is a film having the soft nature with the rich flexibility. Further, according to the barrier thin film of the present invention, permeation of the water and oxygen can be prevented and, for example, the light emitting performance and the life of the organic EL element can certainly be prolonged so as to improve the reliability since the front side is a film having the hard nature with the rich barrier property unlike the above-mentioned rear side. Furthermore, according to the barrier thin film of the present invention, although it is a barrier thin film having such different properties, the thin film itself is composed of a single layer having its property changing continuously, and therefore it has a strong durability against the external impact as compared with the structure with a plurality of thin films laminated, and it cannot be delaminated. Still further, since the thin film is composed of a single layer, it can be produced in one chamber so as to simplify the production process and reduce the production cost as well.

The barrier thin film of the present invention is not limited to the above-mentioned embodiments. Although the barrier thin film aiming at the protection of the organic EL element has been presented in the above-mentioned embodiments, the barrier thin film can be also applied for, for example, protection of a solar battery.

Therefore, any one having substantially the same configuration and providing the same effects as the technological idea disclosed in the claims can be included in the technological scope of the barrier thin film of the present invention.

1. A barrier thin film for preventing permeation of water and oxygen from the outside, the barrier thin film comprising a property changing continuously from its one side surface to the other side surface.

2. The barrier thin film according to claim 1, wherein the barrier thin film is made with an inorganic substance as a main component with the hardness changing continuously from the low hardness to the high hardness.

3. The barrier thin film according to claim 2, wherein the barrier thin film contains carbon and/or hydrogen, the content thereof changing continuously from a high content to a low content.

4. The barrier thin film according to claim 1, wherein the barrier thin film is used for protecting the organic EL layer from the water or the oxygen in an organic EL element.

5. An organic EL element comprising using the barrier thin film according to claim 1.

6. The barrier thin film according to claim 2, wherein the barrier thin film is used for protecting the organic EL layer from the water or the oxygen in an organic EL element.

7. The barrier thin film according to claim 3, wherein the barrier thin film is used for protecting the organic EL layer from the water or the oxygen in an organic EL element.

8. An organic EL element comprising using the barrier thin film according to claim 2.

9. An organic EL element comprising using the barrier thin film according to claim 3.
